(19) United States
(12) Patent Application Publication
(10) Pub. No.: US 2023/0097346 A1
(43) Pub. Date: Mar. 30, 2023

(54) FLOW GUIDE APPARATUSES FOR FLOW UNIFORMITY CONTROL IN PROCESS CHAMBERS

(71) Applicant: Applied Materials, Inc., Santa Clara, CA (US)

(72) Inventors: Jiheng Zhao, San Jose, CA (US); Guangwei Sun, San Jose, CA (US); Jrjyan Jerry Chen, Campbell, CA (US); Jeffrey Kho, Monte Sereno, CA (US)

(21) Appl. No.: 17/490,012

(22) Filed: Sep. 30, 2021

(51) Int. Cl. C23C 16/455; H01L 21/67

(52) U.S. Cl. CPC C23C 16/45502; C23C 16/45559; H01L 21/67253; C23C 16/45572

(57) ABSTRACT

A flow guide apparatus includes an upper flow guide structure configured to receive a first gas from a remote source, and a lower flow guide structure attached to the upper flow guide structure. The upper flow guide structure and the lower flow guide structure are configured to receive at least one gas from at least one remote source. The flow guide apparatus further includes a line diffuser structure disposed between the lower flow guide structure and the upper flow guide structure. The line diffuser structure has a long axis along a length of the upper flow guide structure and a short axis. The line diffuser structure includes a plurality of through holes that are configured to approximately evenly distribute the at least one gas as it is output into a reactor.

### TECHNICAL FIELD

The instant specification generally relates to electronic device fabrication. More specifically, the instant specification relates to flow guide apparatuses for flow uniformity control of gas distribution within a process chamber.

### BACKGROUND

An electronic device manufacturing apparatus can include multiple chambers, such as process chambers and load lock chambers. Such an electronic device manufacturing apparatus can employ a robot apparatus in the transfer chamber that is configured to transport substrates between the multiple chambers. In some instances, multiple substrates are transferred together.

Process chambers may be used in an electronic device manufacturing apparatus to perform one or more processes on substrates, such as deposition processes and etch processes. Traditionally, the flow of process gases into process chambers is non-uniform. Such non-uniformity in the gas flow can cause some regions of substrates to be exposed to more process gases than other regions of the substrates. As a result, films resulting from the deposition and/or etch processes may be non-uniform.

### SUMMARY

In accordance with an embodiment, a flow guide apparatus for a process chamber is provided. The flow guide apparatus includes an upper flow guide structure configured to receive a first gas from a remote source, and a lower flow guide structure attached to the upper flow guide structure. The upper flow guide structure and the lower flow guide structure are configured to receive at least one gas from at least one remote source. The flow guide apparatus further includes a line diffuser structure disposed between the lower flow guide structure and the upper flow guide structure. The line diffuser structure has a long axis along a length of the upper flow guide structure and a short axis. The line diffuser structure includes a plurality of through holes that are configured to approximately evenly distribute the at least one gas as it is output into a reactor area.

In accordance with another embodiment, a deposition chamber system is provided. The deposition chamber system includes an upstream section to receive at least one gas from at least one remote source, a reactor area to perform a deposition process to deposit material onto a substrate using the at least one gas, a downstream section to remove remnants of the deposition process from the reactor area, and at least one flow guide apparatus located within the upstream section. The at least one flow guide apparatus includes an upper flow guide structure, and a lower flow guide structure attached to the upper flow guide structure. The upper flow guide structure and the lower flow guide are configured to receive the at least one gas from the at least one remote source. The at least one flow guide apparatus further includes a line diffuser structure disposed between the lower flow guide structure and the upper flow guide structure. The line diffuser structure has a long axis along a length of the upper flow guide structure and a short axis. The line diffuser structure includes a plurality of through holes that are configured to approximately evenly distribute the at least one gas as it is output into the reactor area.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIGS. 1A and 1B are views of an example deposition chamber system, in accordance with some embodiments.

FIGS. 2A-2D are views of an example flow guide apparatus of a deposition chamber system, in accordance with some embodiments.

FIG. 3 is a perspective view of an example line diffuser block, in accordance with some embodiments.

FIG. 4 is a top-down view of an example line diffuser aligner for aligning and positioning line diffuser blocks, in accordance with some embodiments.

FIGS. 5A and 5B are cross-sectional views of an example channel flows through an upper flow guide structure of a flow guide apparatus, in accordance with some embodiments.

FIG. 6 is a flow chart of a method for fabricating an example flow guide apparatus, in accordance with some embodiments.

### DETAILED DESCRIPTION

Deposition chamber systems, such as atomic layer deposition (ALD) chamber systems and chemical vapor deposition (CVD) chamber systems, utilize a process gas flow to perform a deposition process (e.g., ALD or CVD) to deposit material (e.g., a thin film) onto a substrate or wafer. The process gas flow can include reactant gases that react to form a particular material on the substrate. The process gas flow can further include an inert gas. The inert gas can be excited by plasma generated within the reactor during, for example, a plasma-enhanced ALD process (PE-ALD), which can accelerate the inert gas into the substrate to sputter etch the material being formed on the substrate. One example of a material that can be deposited using a deposition process is a silicon oxide (SiOₓ). For example, silicon monoxide (SiO) thin films can be used to enable organic light-emitting diode (OLED) surface passivation after the formation of an OLED cathode.

Generally, a deposition chamber system can include an upstream section for receiving the process gas flow, a reactor chamber for depositing the material onto a substrate using the process gas flow, and a downstream section for evacuating residual process gas flow and byproducts of the deposition process from the deposition chamber system. A flow guide apparatus can be included in the upstream section and/or the downstream section to guide the process gas flow into the reactor chamber or out of the reactor chamber, respectively. The amount of reactant gas flow can impact the deposition flow rate (e.g., increased reactant gas flow can lead to an increased deposition rate), and the amount of inert gas flow can impact the etch flow rate (e.g., increased inert gas flow rate can lead to an increased etch rate). However, in some instances, the flow guide apparatus can lead to a non-uniform distribution of process gas flow rates. This can lead to poor mixing of the components of the process gas flow, and thus lead to less desirable combinations of deposition rates and etch rates resulting in reduced material deposition uniformity.

Aspects and implementations of the present disclosure address these and other shortcomings of existing technologies by providing flow guide apparatuses for flow uniformity control. In some embodiments, a flow guide apparatus can be used in a deposition chamber system to enable process gas flow uniformity control. For example, the deposition chamber system can be an ALD chamber system. As another example, the deposition chamber system can be a chemical vapor deposition (CVD) chamber system. Aspects and implementations of the present disclosure result in technological advantages over other approaches. For example, the use of a flow guide apparatus for flow uniformity control as described herein, as compared to the use of other flow guides, can enable improved gas flow mixing uniformity without sacrificing process chamber size and/or increased footprint. Improved gas flow mixing uniformity can result in improved material deposition (e.g., thin film) uniformity and in-situ clean rate.

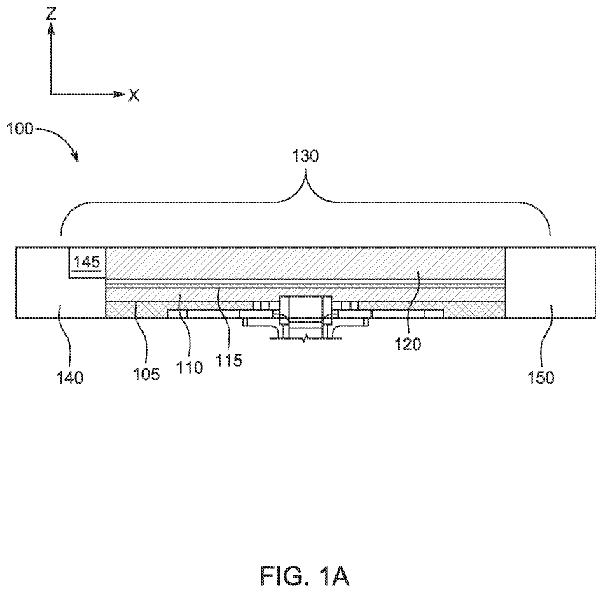

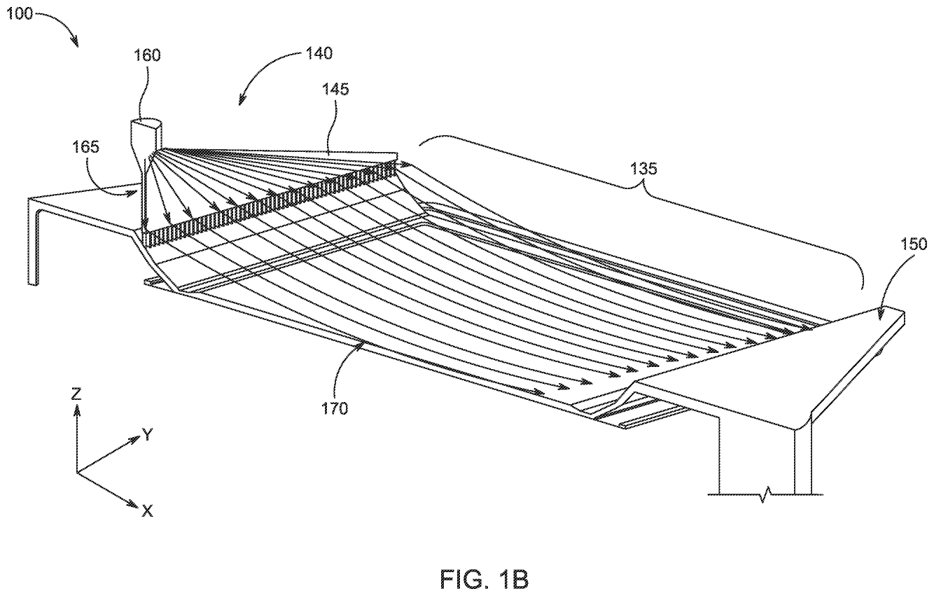

FIGS. 1A and 1B are views of a deposition chamber system 100, in accordance with some embodiments. More specifically, FIG. 1A is a cross-sectional view of the deposition chamber system 100 showing a slice on an X-Z plane, and FIG. 1B is a perspective view of the deposition chamber system 100, also sliced along the X-Z plane approximately at a center of the deposition chamber system 100 along the Y-axis (e.g., so that half of the deposition chamber system is shown). In some embodiments, the deposition chamber system 100 includes an ALD chamber system. However, the deposition chamber system 100 can include any suitable deposition chamber in accordance with the embodiments described herein. For example, in some embodiments, the deposition chamber system 100 includes a CVD chamber system.

As shown in FIG. 1A, the system 100 includes a susceptor 110, a cathode 120, and a reactor area or process chamber 130 between the susceptor 110 and the cathode 120. The susceptor 110 is configured to receive a substrate (not shown in FIG. 1A), raise the substrate into the reactor area 130 to perform a deposition process, and maintain the substrate within the reactor area 130 during processing. A susceptor includes a material that can either heat or cool the substrate disposed thereon to a temperature within a certain range. Susceptor design (e.g., material choice) can depend on the reactor operating temperature(s). The susceptor 110 can be made of a suitable material that can heat and/or cool the substrate to a desired processing temperature. Examples of suitable materials for the susceptor 110 include aluminum (Al), stainless steel, and ceramic. In some embodiments, the susceptor 110 includes a ceramic material. For example, the susceptor 110 can include a silicon carbide (SiC) material, although such an example should not be considered limiting. The susceptor 110 can be provided with a protective coating to protect the susceptor 110 during processing. In some embodiments, the protective coating is a plasma-resistant coating. For example, the protective coating can include Y₂O₃ or other similar material. Other examples of plasma-resistant coatings that may be used include Er₂O₃, Y₃Al₅O₁₂ (YAG), Er₃Al₅O₁₂ (EAG), a composition comprising Y2O3 and ZrO2 (e.g., a Y2O3-ZrO2 solid solution), a composition comprising Y2O3, Al2O3 and ZrO2 (e.g., a composition comprising Y₄Al₂O₉ and a solid-solution of Y₂O₃−ZrO₂), Y—O—F (e.g., Y₅O₄F₇), YF₃, and so on. The coatings may have been deposited by line-of sight or non-line-of-sight deposition processes, such as ALD, CVD, physical vapor deposition (PVD), ion-assisted deposition (IAD), and so on.

The cathode 120 can include any suitable conductive material in accordance with the embodiments described herein. For example, the cathode 120 can include aluminum (Al). The cathode 120 can be provided with a protective coating to protect the cathode 120 during processing. In some embodiments, the protective coating is a plasma-resistant coating. For example, the protective coating can include Y₂O₃ or other similar material. Any of the other plasma-resistant coatings discussed herein may also be used to coat the cathode 120.

As shown, the system 100 further includes an upstream section 140 and a downstream section 150. Although the upstream section 140 is shown on the left side of the system 100 and the downstream section 150 is shown in the right side of the system 100, such an arrangement should not be considered limiting. The upstream section 140 is designed to support and flow a process gas flow upstream into the reactor of the system 100 for the deposition process. For example, the process gas flow can include gases that are introduced into the reactor to perform the deposition process. The process gas flow can be combined with a plasma (e.g., a plasma-enhanced deposition process). For example, the process gas can be used to form a plasma in the reactor area 130, or a remote plasma may be formed and delivered into the reactor area 130 with the process gas. In embodiments, the upstream section 140 includes a flow guide apparatus 145. A long axis of the flow guide apparatus may be orthogonal to the cross sectional view (e.g., be parallel with the X-axis). The flow guide apparatus 145 may deliver process gases into the reactor area of the process chamber 130 in an approximately evenly distributed manner. In the illustrated example, the flow guide apparatus 145 evenly distributes the process gases along the X-axis, and the process gases then flow out of the flow guide apparatus and into the reactor from left to right. The flow guide apparatus 145 is discussed in greater detail below. The downstream section 150 is designed to remove or evacuate remnants of the deposition process from the reactor area 130, which can include residual gases (e.g., unreacted gases) and/or byproducts.

As shown in FIG. 1B, the deposition chamber system 100 includes a reactor area 135 within the reactor area or process chamber 130, and at least the upstream section 140 includes a flow guide apparatus 145 including an upper flow guide structure, a lower flow guide structure, and a line diffuser structure. Process gases may enter the flow guide apparatus 145 via a gas inlet 160, and may be approximately evenly distributed by the flow guide apparatus 145 so that the gases are approximately evenly distributed as they enter the reactor area 135. Arrows 165 show the process gas flows within the flow guide apparatus 145, and arrows 170 show the process gas flows within the reactor area 135 after they leave the flow guide apparatus 145. As shown, the process gases are approximately evenly distributed by the flow guide apparatus 145. The long axis of the flow guide apparatus may correspond to the X-axis in embodiments, and the short axis of the flow guide structure may correspond to the Y-axis in embodiments. Accordingly, the long axis of the flow guide structure may be approximately perpendicular to a direction of gas flow within the reactor area 135 in embodiments.

A reactor frame (not shown) can be included to hold a substrate in place during the deposition process and can function as a stencil to define the film deposition boundary area on the substrate. Furthermore, the reactor frame can close the reactor area 135 to prevent gas leak into other areas of the deposition chamber system 100. For example, a reactor frame can be a mask frame or a shadow frame. A mask frame can be used for smaller electronic devices, such as mobile phones, while a shadow frame can be used for larger electronic devices, such as televisions.

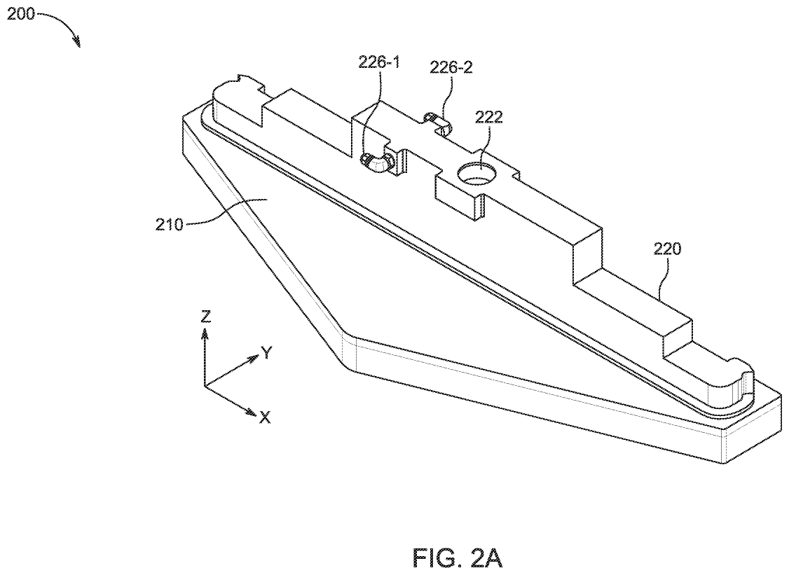

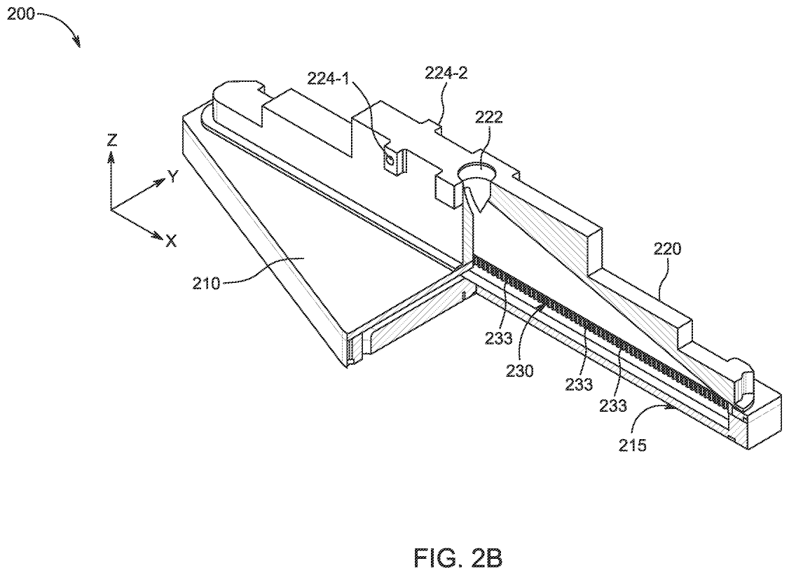

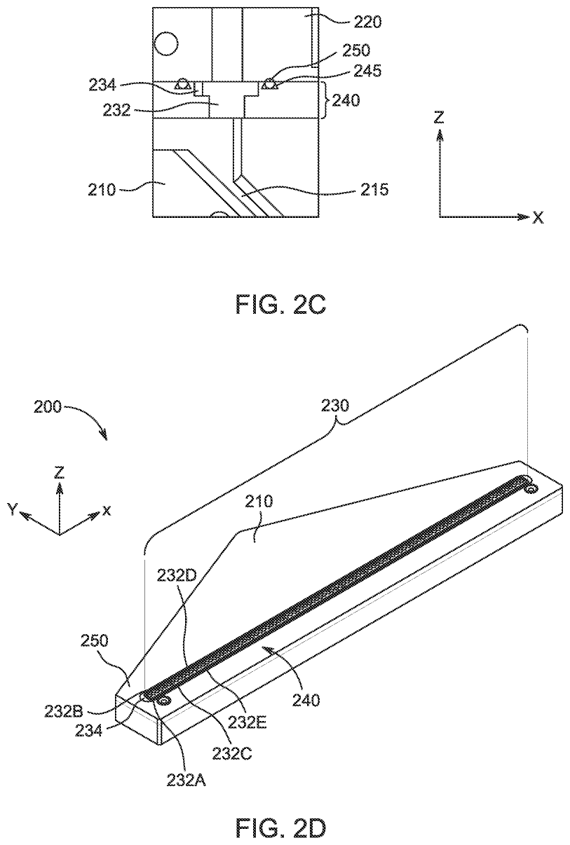

As will be described in further detail herein, the flow guide apparatus 145 including the upper flow guide structure can enable process gas flow uniformity control. For example, the flow guide apparatus 145 can achieve greater uniformity with respect to mixing process gases including a carrier gas of the process gas flow. As will be described in further detail herein, the upper flow guide structure and the lower flow guide structure of the flow guide apparatus 145 are configured to receive at least one gas from at least one remote source. The flow guide apparatus 145 can further include a line diffuser structure disposed between the lower flow guide structure and the upper flow guide structure. The line diffuser structure has a long axis along a length of the upper flow guide structure and a short axis. The line diffuser structure can include a number of through holes that are configured to approximately evenly distribute the at least one gas as it is output into a reactor area 130. In some embodiments, the line diffuser structure can include a number of line diffuser blocks that each include a subset of the through holes, and a line diffuser aligner (e.g., bracket) that aligns and positions the line diffuser blocks within the line diffuser structure along the long axis of the line diffuser structure. Each of the line diffuser blocks can include a particular number of through holes formed on an upper surface of the line diffuser block, where each through hole has a particular diameter selected to enable the uniformity control. For example, each line diffuser block can have three holes, although the number of holes of a particular line diffuser block should not be considered limiting. In some embodiments, each hole of a line diffuser block has a same diameter. In some embodiments, at least one hole of a line diffuser block has a different diameter from another hole of the line diffuser block. Further details regarding the flow guide apparatus will now be described below with reference to FIGS. 2A-6.

FIGS. 2A-2D are views of an example flow guide apparatus 200 for a process chamber, in accordance with some embodiments. In embodiments, flow guide apparatus 200 corresponds to flow guide apparatus 145 of FIGS. 1A-B. For example, FIGS. 2A and 2B are perspective views of the flow guide apparatus 200 (where FIG. 2B shows an interior of the flow guide apparatus after slicing the flow guide apparatus along the Y-Z plane and the X-Y plane), FIG. 2C is a cross-sectional view of a portion of the flow guide apparatus 200 sliced along the X-Z plane, and FIG. 2D is a perspective view of a portion of the flow guide apparatus 200. The flow guide apparatus 200 can be included in an upstream section and/or a downstream section of a deposition chamber system (e.g., the upstream section 140 and/or the downstream section 150 of FIG. 1). However, the flow guide apparatus 200 can be utilized in any suitable implementation to enable uniform flow uniformity control (e.g., uniform gas flow mixing), in accordance with the embodiments described herein.

As shown in FIGS. 2A-2D, the flow guide apparatus 200 can include a lower flow guide structure 210 and an upper flow guide structure 220. The lower flow guide structure 210 can include a flow guide 215 that may direct process gases at an angle into a process chamber. The upper flow guide structure 220 can include a gas inlet opening 222 that may connect to one or more gas supply conduits, a coolant supply flow opening or inlet 224-1 and a coolant return flow opening or outlet 224-2. A coolant supply flow connector 226-1 can be integrated into the coolant supply flow opening 224-1 and a coolant return flow connector 226-2 can be integrated into the coolant return flow opening 224-2. At least one of the lower flow guide structure 210 or the upper flow guide structure 220 is configured to receive at least one gas from at least one remote source (e.g., at the gas inlet opening 222) to be introduced into a reactor area of the process chamber.

As further shown in FIGS. 2A-2D, the flow guide apparatus 200 can further include a line diffuser structure 230 disposed between the lower flow guide structure 210 and the upper flow guide structure 220. In some embodiments, the line diffuser structure 230 is attached to and/or integrated with the lower flow guide structure 210. The line diffuser structure 230 has a long axis along a length of the upper flow guide structure 220 and a short axis and a vertical axis.

As shown in FIG. 2B, an interior of a first half of the upper flow guide structure 220 includes an internal cavity that is tapered in a first direction from the center opening (e.g., gas inlet) to the outer edges of the line diffuser structure 230. Although not shown, a second half of the internal cavity of the flow guide structure 220 is tapered in a second direction from the center opening, and may have a same angle as the taper in the first half. A narrowest portion of the internal cavity of the upper flow guide structure 220 may approximately correspond to the diameter of the gas inlet opening 222, and a widest portion of the internal cavity (along the long axis of the flow guide apparatus 200) may approximately correspond to a length of the line diffuser structure.

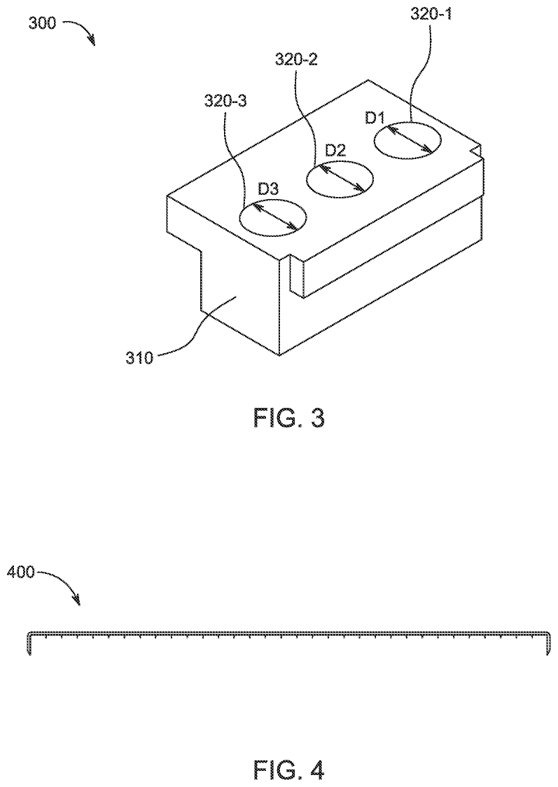

As will be described in further detail below with reference to FIGS. 3 and 4, the line diffuser structure 230 can include a number of through holes 233 that are configured to approximately evenly distribute the gas as it is output into the reactor area. In some embodiments, the line diffuser structure 230 can include a number of line diffuser blocks, including line diffuser block 232, that each include a subset of the through holes, and a line diffuser aligner (“aligner”) 234 that aligns and positions the line diffuser blocks within the line diffuser structure 230 along the long axis of the line diffuser structure 230. Each of the line diffuser blocks can include a particular number of through holes formed on an upper surface of the line diffuser block, where each through hole has a particular diameter selected to enable flow uniformity control (e.g., improved gas flow mixing uniformity). For example, each line diffuser block can have three holes, although the number of holes of a particular line diffuser block should not be considered limiting. In some embodiments, each hole of a line diffuser block has a same diameter. In some embodiments, at least one hole of a line diffuser block has a different diameter from another hole of the line diffuser block. The number of line diffuser blocks that can fit into the line diffuser structure 230 can depend on the geometry of each of the line diffuser blocks (e.g., line diffuser block 232) and the geometry of the lower flow guide structure 210. In some embodiments, the line diffuser blocks 232 may have a T-shaped cross section, as shown in FIG. 2C.

The line diffuser structure 230 can be disposed in a trench structure 240. The trench structure 240 can include a first rectangular trench having a first width milled into a first side of the aligner 234 and a second rectangular trench having a second width milled into an opposite second side of the aligner 234. The first and second rectangular trenches may meet, forming a stepped region within the aligner 234 that can receive the line diffuser blocks (e.g., having the T-shaped cross section). In an example, the number of line diffuser blocks that can fit into the line diffuser structure 230 can be based at least in part on the lengths of each line diffuser block. Line diffuser blocks may all have the same dimensions and/or number of holes, or may have different dimensions and/or numbers of holes.

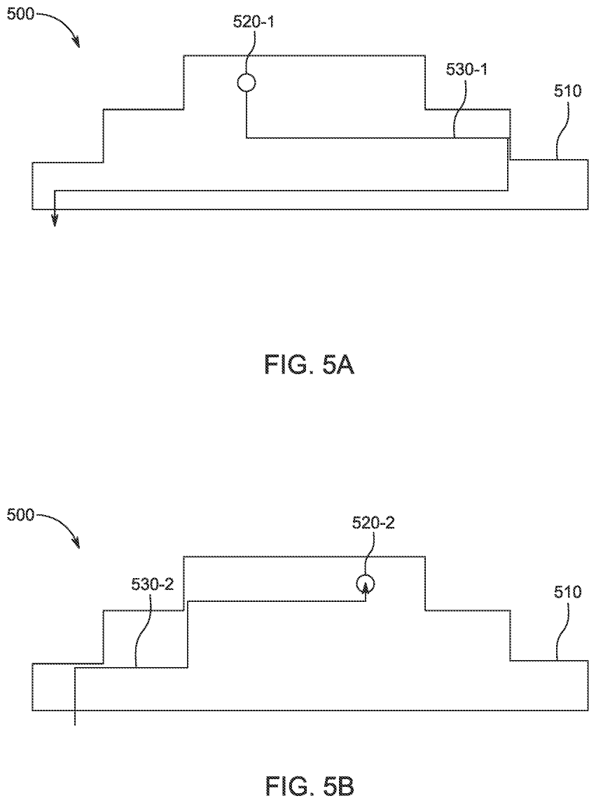

As will be described in further detail below with reference to FIGS. 5A and 5B, the coolant supply flow connector 226-1 can connect to a pipe or tubing to enable the entrance of a coolant flow from the coolant supply flow opening 224-1 to the bottom of the upper flow guide structure 220, and the coolant return flow connector 226-2 can connect to a pipe or tubing to enable the exit of the coolant flow from the bottom of the upper flow guide structure 220 to the coolant return flow opening 224-2. That is, the upper flow guide structure 220 can include a coolant delivery system having a coolant supply flow opening that is configured to receive an unheated coolant, one or more channels configured to circulate the coolant within the upper flow guide structure, and a coolant return flow opening configured to output the coolant after the coolant has been circulated within the upper flow guide structure 220 via the one or more channels and heated by the upper flow guide structure.

As further shown in FIG. 2C and 2D, a groove 245 can encircle the line diffuser structure 230 including the line diffuser block 232 and the aligner 234. Many line diffuser blocks 232A-E may be arranged in the aligner 234 along the long axis of the line diffuser structure 230 and flow guide apparatus 200. Each of the line diffuser blocks 232A-E may have multiple holes aligned with the long axis of the line diffuser structure 230. A sealing structure 250 can be disposed within the groove 245 to seal the upper flow guide section 220 to the lower flow guide section, thereby forming a seal between the upper flow guide structure 220 and the lower flow guide structure 210 around the line diffuser structure 230. For example, the sealing structure 250 can be an O-ring, a gasket, etc., made from any suitable material in accordance with embodiments described herein.

FIG. 3 is a perspective view of an example line diffuser block 300, in accordance with some embodiments. For example, the line diffuser block 300 can correspond to the line diffuser block(s) 232, 232A-E described above with reference to FIGS. 2A-2D. As shown, the line diffuser block 300 includes a base structure 310, and a number of through holes (“holes”) 320-1 through 320-3 formed within the base structure 310. In one embodiment, as shown, holes 320-1 and 320-3 are disposed approximately at respective ends of the line diffuser block 300, and hole 320-2 is disposed approximately at a center of the line diffuser block 300. Although three holes 320-1 through 320-3 are shown in FIG. 3, the number of holes should not be considered limiting. Additionally, in some embodiments line diffuser blocks are omitted, and holes are drilled directly into the lower flow guide section to form the line diffuser structure. The line diffuser block 300 can include any suitable material in accordance with embodiments described herein. In some embodiments, the line diffuser block 300 includes a metal material. For example, the line diffuser block 300 can include aluminum (Al). In some embodiments, the line diffuser block 300 includes a ceramic material. For example, the ceramic material can include aluminum oxide (Al₂O₃). However, any suitable ceramic material can be used in accordance with embodiments described herein.

The holes 320-1 through 320-3 form a pattern defined at least in part by the diameter of each of the holes 320-1 through 320-3. For example, the hole 320-1 can have a diameter “D1,” the hole 320-2 can have a diameter “D2,” and the hole 320-3 can have a diameter “D3.” The diameters D1 through D3 can have any suitable length or value in accordance with the embodiments described herein. In some embodiments, the length/value of each of the diameters D1 through D3 can range between about 1 mm to about 10 mm. In some embodiments, all line diffuser blocks have a same number of holes having a same geometry (e.g., all having a same diameter). In other embodiments, different line diffuser blocks have different hole arrangements (e.g., different numbers of holes, different positions of holes and/or different diameters of holes). In some embodiments, holes are perpendicular to an upper surface of the line diffuser blocks. Alternatively, one or more holes may be angled relative to the upper surface of the line diffuser blocks. In some embodiments, a diameter of the holes remains consistent throughout the holes. Alternatively, one or more holes may have tapered internal diameters (e.g., where they have a larger diameter on a face that faces towards the upper flow guide structure and a smaller diameter on a face that faces away from the upper flow guide structure or a larger diameter on a face that faces away from the upper flow guide structure and a smaller diameter on a face that faces toward the upper flow guide structure).

In some embodiments, the diameters D1 through D3 can have a different length or value. In some embodiments, each of the diameters D1 through D3 can be the same length. For example, each of the diameters D1 through D3 can have a length of about 5 mm. As another example, each of the diameters D1 through D3 can have a length of about 6 mm. As yet another example, each of the diameters D1 through D3 can have a length of about 7 mm. As yet another example, each of the diameters D1 through D3 can have a length of about 8 mm. Thus, in some embodiments, D1 through D3 can each have a diameter of approximately 5-8 mm. Alternatively, at least one of the diameters D1 through D3 can have a different length.

The diameter D2 can be different from at least one of the diameters D1 and D3. In some embodiments, the diameters D1 and D3 have the same length, and the diameter D2, has a different length from the diameters D1 and D3. For example, the diameters D1 and D3 can have a length of about 9.9 mm, and the diameter D2 can have a length of about 2 mm. As another example, the diameters D1 and D3 can have a length of about 4 mm, and the diameter D2 can have a length of about 8 mm. As yet another example, the diameters D1 and D3 can have a length of about 6 mm, and the diameter D2 can have a length of about 8 mm. As yet another example, the diameters D1 and D3 can have a length of about 8 mm, and the diameter D2 can have a length of about 6 mm. Therefore, in some embodiments, the diameter D2 is approximately 2-6 mm and the diameters D1 and D3 are each approximately 8-10 mm and, in some embodiments, the diameter D2 is approximately 8-10 mm and the diameters D1 and D3 are each approximately 4-6 mm.

FIG. 4 is a top-down view of a line diffuser aligner (“aligner”) 400, in accordance with some embodiments. For example, the aligner 400 can be similar to the aligner 234 described above with reference to FIGS. 2A-2D to align and position a number of line diffuser blocks (e.g., line diffuser blocks 232A-E described above with reference to FIGS. 2A-2D and/or the line diffuser block 300 described above with reference to FIG. 3).

As described above, a line diffuser structure can be formed from a number of individual line diffuser blocks. Forming a line diffuser structure from a number of individual line diffuser blocks can enable interchangeability of line diffuser blocks having different through hole arrangements. Accordingly, a line diffuser structure formed from a number of individual line diffuser blocks can provide for a more seamless through hole pattern adjustment along the length of the line diffuser apparatus for testing flow uniformity with respect to a variety of different flow conditions and/or process recipes.

In alternative embodiments, instead of being formed from a number of individual line diffuser blocks, the line diffuser structure can formed from a single line diffuser block formed from a continuous piece of material having a number of through holes formed thereon that extend the length of the continuous piece of material. In some embodiments, each of the through holes has a same diameter. In some embodiments, at least one of the through holes has a different diameter. For example, once a through hole pattern and process recipe are finalized to achieve a suitable flow condition using a number of individual line diffuser blocks, the individual line diffuser blocks can be replaced with the single line diffuser block having a similar through hole formation.

FIGS. 5A and 5B are cross-sectional views of coolant flows through a flow guide apparatus 500. More specifically, FIG. 5A shows the flow guide apparatus 500 from a first side, and FIG. 5B shows the flow guide apparatus 500 from a second side opposite the first side (e.g., 180 degree rotation). The flow guide apparatus 500 includes a flow guide structure 510 (e.g., the upper flow guide structure 220 described above with reference to FIGS. 2A-2D). The flow guide structure 510 can include a coolant supply flow opening 520-1 (e.g., the coolant supply flow opening 224-1 described above with reference to FIGS. 2A-2D) and a coolant return flow opening 520-2 (e.g., the coolant return flow opening 224-2 described above with reference to FIGS. 2A-2D). The coolant supply flow opening 520-1 and the coolant return flow opening 520-2 are located directly across from each other (similar to the coolant supply flow opening 224-1 and the coolant return flow opening 224-2).

FIG. 5A illustrates a coolant supply flow through one or more channels 530-1 of the flow guide structure 510. For example, the coolant supply flow can enter through the coolant supply flow opening 520-1 and proceed in a snake-like fashion through the one or more channels 530-1. The coolant supply flow can then exit through a first opening at the bottom of the flow guide structure 500.

FIG. 5B illustrates a coolant return flow through one or more channels 530-2 of the flow guide structure 500. For example, the coolant return flow can enter through a second opening at the bottom of the flow guide structure 500 and proceed in a snake-like fashion through the one or more channels 530-2. The coolant return flow can then exit through the coolant return flow opening 520-2.

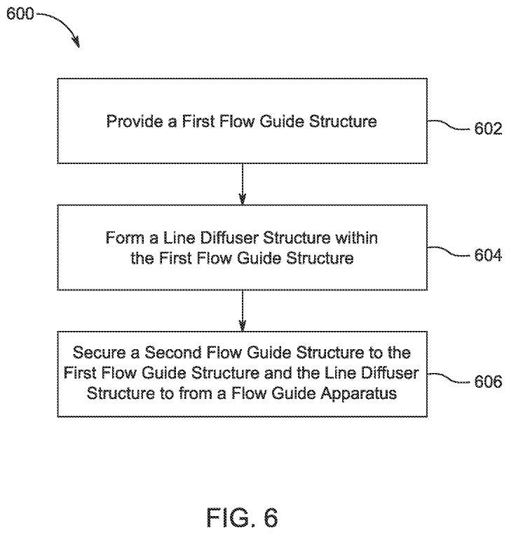

FIG. 6 depicts a flow chart of a method 700 for fabricating an example flow guide apparatus, in accordance with some embodiments. The flow guide apparatus can be used to enable uniform flow control. In some embodiments, flow guide apparatus can be included within a deposition chamber system to enable uniform process gas flow control (e.g., uniform process gas flow mixing).

At block 602, a first flow guide structure is provided. For example, the first flow guide structure can be a lower flow guide structure. At block 604, a line diffuser structure is formed within the first flow guide structure. The line diffuser structure can include a line diffuser bracket, and forming the line diffuser structure can further include using the line diffuser bracket to align and position the line diffuser blocks. Each of the line diffuser blocks can include a number of holes formed on an upper surface of the line diffuser block to enable uniform flow control. For example, each of the line diffuser blocks can include three holes (e.g., a center hole and two end holes).

At block 606, a second flow guide structure is secured to the first flow guide structure and the line diffuser structure to form a flow guide apparatus. For example, the second flow guide structure can be an upper flow guide structure disposed above the lower flow guide structure and the line diffuser structure. In alternative embodiments, the first flow guide structure can be the upper flow guide structure and the second flow guide structure can be lower flow guide structure, such that the flow guide apparatus is formed by securing the lower flow guide structure below the upper flow guide structure. Further details regarding blocks 602-606 are described above with reference to FIGS. 1-5B.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A flow guide apparatus for a process chamber, comprising:
an upper flow guide structure;
a lower flow guide structure attached to the upper flow guide structure, the upper flow guide structure and the lower flow guide structure being configured to receive at least one gas from at least one remote source; and
a line diffuser structure disposed between the lower flow guide structure and the upper flow guide structure, the line diffuser structure having a long axis along a length of the upper flow guide structure and a short axis, wherein the line diffuser structure comprises a plurality of through holes arranged along the long axis configured to approximately evenly distribute the at least one gas as it is output into a reactor area.

2. The flow guide apparatus of claim 1, wherein the line diffuser structure further comprises a plurality of line diffuser blocks each comprising a subset of the plurality of through holes and a line diffuser aligner that aligns and positions the plurality of line diffuser blocks within the line diffuser structure along the long axis of the line diffuser structure.

3. The flow guide apparatus of claim 2, wherein at least one line diffuser block of the plurality of line diffuser blocks comprises a first through hole having a first diameter disposed approximately at a center of the line diffuser block, a second through hole having a second diameter disposed approximately at a first end of the line diffuser block, and a third through hole having a third diameter disposed approximately at a second end of the line diffuser block.

4. The flow guide apparatus of claim 3, wherein the first diameter, the second diameter and the third diameter each have a same length.

5. The flow guide apparatus of claim 4, wherein the first diameter, the second diameter and the third diameter are each approximately 5-8 mm.

6. The flow guide apparatus of claim 3, wherein the first diameter is different from at least the second diameter.

7. The flow guide apparatus of claim 6, wherein the first diameter is greater than the second diameter.

8. The flow guide apparatus of claim 6, wherein the first diameter is approximately 2-6 mm and the second diameter is approximately 8-10 mm.

9. The flow guide apparatus of claim 6, wherein the first diameter is approximately 8-10 mm and the second diameter is approximately 4-6 mm.

10. The flow guide apparatus of claim 1, wherein the upper flow guide structure comprises a coolant delivery system comprising a supply flow opening that is configured to receive an unheated coolant, one or more channels configured to circulate the coolant within the upper flow guide structure, and a coolant return flow opening configured to output the coolant after the coolant has been circulated within the upper flow guide structure via the one or more channels and heated by the upper flow guide structure.

11. The flow guide apparatus of claim 1, wherein:
the at least one of the upper flow guide section or the lower flow guide section comprises a groove that encircles the line diffuser structure; and
the flow guide apparatus further comprises a sealing structure disposed within the groove to seal the upper flow guide section to the lower flow guide section.

12. A deposition chamber system comprising:
an upstream section to receive at least one gas from at least one remote source;
a reactor area to perform a deposition process to deposit material onto a substrate using the at least one gas;
a downstream section to remove remnants of the deposition process from the reactor area; and
at least one flow guide apparatus located within or attached to the upstream section, the at least one flow guide apparatus comprising:
an upper flow guide structure;
a lower flow guide structure attached to the upper flow guide structure, the upper flow guide structure and the lower flow guide structure being configured to receive the at least one gas from the at least one remote source; and
a line diffuser structure disposed between the lower flow guide structure and the upper flow guide structure, the line diffuser structure having a long axis along a length of the upper flow guide structure and a short axis, wherein the line diffuser structure comprises a plurality of through holes that are configured to approximately evenly distribute the at least one gas as it is output into the reactor area.

13. The deposition chamber system of claim 12, wherein the line diffuser structure further comprises a plurality of line diffuser blocks each comprising a subset of the plurality of through holes and a line diffuser aligner that aligns and positions the plurality of line diffuser blocks within the line diffuser structure along the long axis of the line diffuser structure.

14. The deposition chamber system of claim 12, wherein at least one line diffuser block of the plurality of line diffuser blocks comprises a first through hole having a first diameter disposed approximately at a center of the line diffuser block, a second through hole having a second diameter disposed approximately at a first end of the line diffuser block, and a third through hole disposed approximately at a second end of the line diffuser block.

15. The deposition chamber system of claim 14, wherein the first diameter, the second diameter and the third diameter each have a same length.

16. The deposition chamber system of claim 15, wherein the first diameter, the second diameter and the third diameter are each approximately 5-8 mm.

17. The deposition chamber system of claim 14, wherein the first diameter is approximately 2-6 mm and the second diameter is approximately 8-10 mm.

18. The deposition chamber system of claim 14, wherein the first diameter is approximately 8-10 mm and the second diameter is approximately 4-6 mm.

19. The deposition chamber system of claim 12, wherein the upper flow guide structure comprises a coolant delivery system comprising a supply flow opening that is configured to receive an unheated coolant, one or more channels configured to circulate the coolant within the upper flow guide structure, and a coolant return flow opening configured to output the coolant after the coolant has been circulated within the upper flow guide structure via the one or more channels and heated by the upper flow guide structure.

20. The deposition chamber system of claim 12, wherein:
the at least one of the upper flow guide section or the lower flow guide section comprises a groove that encircles the line diffuser structure; and
the flow guide apparatus further comprises a sealing structure disposed within the groove to seal the upper flow guide section to the lower guide section.
